(19) United States
(12) Patent Application Publication
(10) Pub. No.: US 2015/0129901 A1
(43) Pub. Date: May 14, 2015

(54) Optoelectronic Semiconductor Chip and Method for Producing an Optoelectronic Semiconductor Chip

(71) Applicant: OSRAM Opto Semiconductors GmbH, Regensburg (DE)

(72) Inventors: Lutz Höppel, Alteglofsheim (DE); Norwin von Malm, Nittendorf (DE)

(73) Assignee: OSRAM OPTO SEMICONDUCTORS GMBH, Regensburg (DE)

(21) Appl. No.: 14/415,117

(22) PCT Filed: Jun. 27, 2013
(86) PCT No.: PCT/EP2013/063525

§ 371 Date: Jan. 15, 2015

(30) Foreign Application Priority Data
Jul. 16, 2012 (DE) 10 2012 106 364.8

(51) Int. Cl. H01L 27/15; H01S 5/022; H01L 33/00; H01L 33/62; H01L 33/60

(52) U.S. Cl. CPC H01L 27/15; H01L 33/62; H01L 33/60; H01L 33/005; H01S 5/022; H01L 2933/0066
USPC 257/88; 438/34

(57) ABSTRACT

An optoelectronic semiconductor chip and a method for producing an optoelectronic semiconductor chip are disclosed. In an embodiment an optoelectronic semiconductor chip includes a support having a support top side, a semiconductor layer sequence having an active layer for generating electromagnetic radiation, wherein the active layer is located between an n-type n-layer and a p-type p-layer of the semiconductor layer sequence, wherein the semiconductor layer sequence, as seen in a plan view of the support top side, is patterned into emitter regions arranged next to one another and electrical conductor tracks located on a side of the semiconductor layer sequence facing away from the support, where the electrical conductor tracks include contact surfaces. The chip further includes an n-contact point and a p-contact point for electrically contacting the semiconductor chip, wherein the emitter regions are electrically connected in series via the at least two conductor tracks.

This patent application is a national phase filing under section 371 of PCT/EP2013/063525, filed Jun. 27, 2013, which claims the priority of German patent application 10 2012 106 364.8, filed Jul. 16, 2012, each of which is incorporated herein by reference in its entirety.

### TECHNICAL FIELD

An optoelectronic semiconductor chip is provided. A method for producing such a semiconductor chip is also provided.

### SUMMARY OF THE INVENTION

An embodiment of the invention is to provide an optoelectronic semiconductor chip which can be operated with a comparatively large operating voltage.

In accordance with at least one embodiment, the semiconductor chip is configured for generating electromagnetic radiation. For example, during operation of the semiconductor chip ultraviolet radiation, blue light, green light and/or red light is generated. Preferably, the semiconductor chip is a light-emitting diode chip or a laser diode chip.

In accordance with at least one embodiment, the semiconductor chip includes a support. The support comprises a support top side and a front side opposite thereto. The support is the component which mechanically bears and mechanically supports the semiconductor chip. The support can be the particular component of the semiconductor chip which has the greatest thickness. For example, the thickness of the support is in the range between 75 μm and 500 μm inclusive or between 100 μm and 300 μm inclusive. Alternatively or in addition, the thickness of the support is preferably at least 5% or at least 7.5% and/or at the most 35% or at the most 25% of an average lateral dimension of the semiconductor chip as seen in a plan view of the support top side. In particular, the support is formed from an electrically insulating material. Furthermore, the support is preferably formed in one piece and is formed from a single, contiguous material.

In accordance with at least one embodiment, the semiconductor chip comprises a semiconductor layer sequence. The semiconductor layer sequence comprises at least one active layer for generating electromagnetic radiation. The semiconductor layer sequence also includes an n-type n-layer and a p-type p-layer. The active layer can be formed by a boundary surface between the n-layer and the p-layer. Equally, the active layer can be formed as a single quantum well structure or as a multiple quantum well structure.

The semiconductor layer sequence is based preferably on a III-V-compound semiconductor material. The semiconductor material is, e.g., a nitride compound semiconductor material such as AlₙIn₁₋ₙ₋ₘGaₘN or a phosphide compound semiconductor material such as AlₙIn₁₋ₙ₋ₘGaₘP or even a arsenide compound semiconductor material such as AlₙIn₁₋ₙ₋ₘGaₘAs, where in each case 0≦n≦1, 0≦m≦1 and n+m≦1. The semiconductor layer sequence can comprise dopants and additional component parts. However, for the sake of simplicity only the essential component parts of the crystal lattice of the semiconductor layer sequence, i.e., Al, As, Ga, In, N or P, are stated, even if they can be replaced and/or supplemented partially by small amounts of further substances. Preferably, the semiconductor layer sequence is based upon AlₙIn₁₋ₙ₋ₘGaₘN.

In accordance with at least one embodiment, the semiconductor chip comprises one or several n-contact points and one or several p-contact points. The contact points are configured for electrically contacting the semiconductor chip. For example, the contact points are configured such that the semiconductor chip can be electrically and mechanically attached via the contact points by soldering. Preferably, the semiconductor chip comprises precisely one n-contact point and precisely one p-contact point. Preferably, the n-contact point is electrically directly connected to the n-layer and the p-contact point is electrically directly connected to the p-layer.

In accordance with at least one embodiment, the semiconductor chip comprises several electric conductor tracks, preferably at least two or at least three or at least four conductor tracks. The conductor tracks comprise in particular a metal or a metal alloy or consist thereof. It is likewise possible that the conductor tracks are formed in part from an electrically conductive oxide such as zinc oxide. A conductor track can be an intrinsically contiguous, electrically uninterrupted ohmic conductor.

In accordance with at least one embodiment, the semiconductor layer sequence is patterned, as seen in a plan view of the support top side, into at least two emitter regions arranged next to one another. Preferably, each of the emitter regions is configured to emit radiation during normal use of the semiconductor chip. As seen in plan view, the emitter regions preferably do not overlap. All of the emitter regions are patterned from the same semiconductor layer sequence. A spaced interval between the emitter regions, in the direction in parallel with the support top side, is preferably small. “Small” can mean that the spaced interval is at the most 5 μm or at the most 2 μm.

In accordance with at least one embodiment, the conductor tracks are located on a side of the semiconductor layer sequence facing away from the support. In other words, the semiconductor layer sequence is then located between the support and the conductor tracks.

In accordance with at least one embodiment, all of the emitter regions or at least some of the emitter regions are electrically connected in series via the conductor tracks. In particular, the n-layer of one of the emitter regions is connected to the p-layer of an adjacent emitter region in the current direction. The current direction is determined by the electric series connection. A current flow can be branched within an emitter region. Between adjacent emitter regions a current flow is preferably unbranched and distinct.

According to at least one embodiment, the optoelectronic semiconductor chip comprises a support having a support top side. A semiconductor layer sequence having at least one active layer for generating electromagnetic radiation which is located between an n-type p-layer and a p-type p-layer is mounted on the support top side. The semiconductor chip comprises an n-contact point and a p-contact point for electrically contacting the semiconductor chip. Furthermore, the semiconductor chip includes at least two or at least three electrical conductor tracks. As seen in a plan view of the support top side, the semiconductor layer sequence is patterned into at least two emitter regions which are arranged next to one another. The emitter regions are connected electrically in series via the conductor tracks. The conductor tracks are located on a side of the semiconductor layer sequence facing away from the support.

By a series interlinking of the emitter regions, it is possible to achieve an operating voltage of the semiconductor chip stated above which is many times higher than is typical for a light-emitting diode chip having a single emitter region. The higher operating voltage renders it possible to dispense with a series transformer which converts voltage to a significant extent. This produces higher system efficiency.

In the case of such a semiconductor chip, the series connection of the emitter regions can be performed at chip level. That is to say, in order to produce the series connection no external conductor tracks are required, for instance on a printed circuit board. This simplifies assembly of the series connection of the emitter regions and also reduces the outlay for adjusting the semiconductor chip.

In accordance with at least one embodiment, two conductor tracks which follow one another along the current direction of the series connection penetrate one another. The penetration relates in particular to a direction perpendicular to the support top side. Penetration can mean that in one plane in parallel with the support top side, one conductor track is completely surrounded by a material of another conductor track. The penetrating conductor track is located preferably partially closer to and partially more remotely from the support top side than the partial region of the conductor track which is penetrated. At least for conductor tracks which are not electrically directly connected to the contact points, it is possible that each of these conductor tracks penetrates precisely one other conductor track and that each of these conductor tracks which are not in direct electrical contact with the contact points is penetrated by precisely one other conductor track. The conductor tracks which are in direct electrical contact with the contact points can be formed differently from the other conductor tracks.

In accordance with at least one embodiment, all of the conductor tracks which are not electrically directly connected to the contact points are formed identically within production tolerances. These conductor tracks can merge with one another in a congruent manner by virtue of geometric operations of translation and rotation.

In accordance with at least one embodiment, at least the conductor tracks which are not electrically directly connected to the contact points comprise one or several contact surfaces. The preferably precisely one contact surface is located on the p-layer. In particular, the contact surface is directly electrically connected to the p-layer. Preferably, no further layer or at the most one layer for improving the electrical contact is located between the p-layer and the contact surface. As seen in plan view, the contact surface covers, e.g., at least 50% or at least 70% or at least 85% of the p-layer. Therefore, the p-layer can be covered virtually completely by the contact surface.

In accordance with at least one embodiment, the contact surface comprises one or several openings. The openings are preferably completely surrounded by a material of the contact surface. The openings can then be holes in the contact surface.

In accordance with at least one embodiment, a partial region of a further conductor track extends through the at least one opening of the contact surface of one of the conductor tracks. This further conductor track which penetrates the contact surface extends preferably as far as into the n-layer of the corresponding emitter region and penetrates the at least one active layer.

In accordance with at least one embodiment, at least those conductor tracks which are not directly electrically connected to the contact points comprise an electrically conductive bridge. The bridge is configured for electrically connecting two adjacent electrical emitter regions to one another. The bridge can be formed in the manner of a conductor track or preferably in a planar manner.

In accordance with at least one embodiment, the bridge of one conductor track, as seen in a plan view of the support top side, in each case partially covers the two emitter regions which are electrically connected to one another by the bridge. It is possible that at least 50% or at least 80% of at least one of these emitter regions is covered by the bridge. The emitter regions can thus be almost completely covered by the bridges of the conductor tracks.

In accordance with at least one embodiment, in each case precisely one of the contact surfaces of the conductor tracks is attached to in each case precisely one of the emitter regions. Each of these contact surfaces of these conductor tracks is penetrated by the bridge(s) of precisely one conductor track which is adjacent in the current direction. It is possible that this does not apply for conductor tracks which are electrically directly connected to the contact points.

In accordance with at least one embodiment, all of the contact surfaces lie in a common plane. This common plane is oriented preferably in parallel with the support top side. Partial regions of the bridges extending in parallel with this plane are located preferably further away from the support top side than the contact surfaces. Partial regions of the bridges oriented perpendicularly to this plane can be located in part closer to the support top side than the contact surfaces.

In accordance with at least one embodiment, partial regions of the n-contact point and/or of the p-contact point which extend in parallel with the plane defined by the contact surfaces are further away from the support top side than the contact surfaces. In particular, the contact surfaces can form the parts of the semiconductor chip which are located furthest away from the support top side, at least for the particular half space above the support top side, in which the semiconductor layer sequence is located.

In accordance with at least one embodiment, the conductor tracks or a partial region of the conductor tracks is configured as a reflector for the radiation generated in the active layer. In this case, the conductor tracks preferably comprise, or consist of, a reflective metal such as silver or aluminum.

In accordance with at least one embodiment, the support is a growth substrate for the semiconductor layer sequence. That is to say, the semiconductor layer sequence is then preferably grown directly on the support top side of the support. The support is in particular a sapphire substrate.

In accordance with at least one embodiment, the semiconductor chip is a flip-chip. The semiconductor chip is preferably surface-mountable. Furthermore, the contact points are located preferably in a common plane in parallel with the support top side. The semiconductor chip can be contacted in particular without bond wire. It is possible that the single parts of the semiconductor chip which are in direct contact with an external printed circuit board are then the n-contact point and the p-contact point.

In accordance with at least one embodiment, a radiation main side of the semiconductor chip is formed by the front side of the support opposite to the support top side. The radiation generated in the semiconductor chip during operation is then emitted exclusively or predominantly through the support. In this respect, it is possible that the support is provided with a patterning, in particular a roughening, or with an anti-reflection layer Likewise, optically active elements such as lenses or luminescence conversion materials can be mounted on the support.

In accordance with at least one embodiment, as seen in a plan view of the support top side, conductor tracks which are adjacent in the current direction overlap. That is to say, as seen in plan view the conductor tracks can extend at least in part one above the other. It is possible that these conductor tracks which extend one above the other are electrically connected to one another only via the semiconductor layer sequence. Concerning this point, elements of the semiconductor chip for protecting against damage caused by electrostatic charges, such as ESD protective diodes, might be disregarded.

In accordance with at least one embodiment, the semiconductor layer sequence is completely removed between adjacent emitter regions. There is then no continuous connection consisting of a semiconductor material of the semiconductor layer sequence between adjacent emitter regions. With the exception of the electrical connection by the conductor tracks, the emitter regions can then be completely electrically insulated from one another. In this view, elements for protecting against electrostatic charges can also be disregarded.

In accordance with at least one embodiment, a trench or an intermediate space between the adjacent emitter regions, in particular in the direction in parallel with the support top side, is partially or completely filled with a material. This material is an electrically insulating material. Furthermore, this material is preferably reflective for the radiation generated during operation of the semiconductor chip or does not act in an absorbing manner or does so only to a negligible extent.

In accordance with at least one embodiment, the semiconductor chip comprises precisely one or at least two, three, four or six emitter regions. Alternatively or in addition, the semiconductor chip comprises at the most 24 or at the most 16 or at the most eight emitter regions.

Also provided is a method for producing an optoelectronic semiconductor chip, as described in conjunction with one or several of the aforementioned embodiments. Features of the semiconductor chip are therefore also disclosed for the method and vice versa.

According to at least one embodiment, the method comprises at least or precisely the steps of: providing the support, epitaxially growing the semiconductor layer sequence onto the support top side, applying at least one contact layer for the conductor tracks onto a top side of the semiconductor layer sequence facing away from the support, patterning the at least one contact layer to form contact surfaces of the conductor tracks, patterning the semiconductor layer sequence to form the emitter regions, applying at least one electrically insulating protective layer onto the top side, applying electrically conductive bridges of the conductor tracks, wherein the bridges electrically connect adjacent emitter regions to one another, and applying the n-contact point and the p-contact point.

Preferably, the method steps are performed in the sequence stated. Alternatively, a different sequence is likewise possible, where technically expedient.

### BRIEF DESCRIPTION OF THE DRAWINGS

An optoelectronic semiconductor chip described in this case and a method described in this case will be explained in greater detail hereinafter with reference to the drawing with the aid of exemplified embodiments Like reference numerals designate like elements in the individual figures. However, none of the references are illustrated to scale. Rather, individual elements can be illustrated excessively large for ease of understanding.

In the drawing:

FIGS. 1 to 12 show schematic sectional views of an exemplified embodiment of a method for producing an optoelectronic semiconductor chip described in this case;

FIGS. 13A to 15B show schematic sectional views of conductor tracks for exemplified embodiments of optoelectronic semiconductor chips described in this case; and

FIG. 16A to 16C shows schematic plan views of exemplified embodiments of optoelectronic semiconductor chips described in this case.

### DETAILED DESCRIPTION OF ILLUSTRATIVE EMBODIMENTS

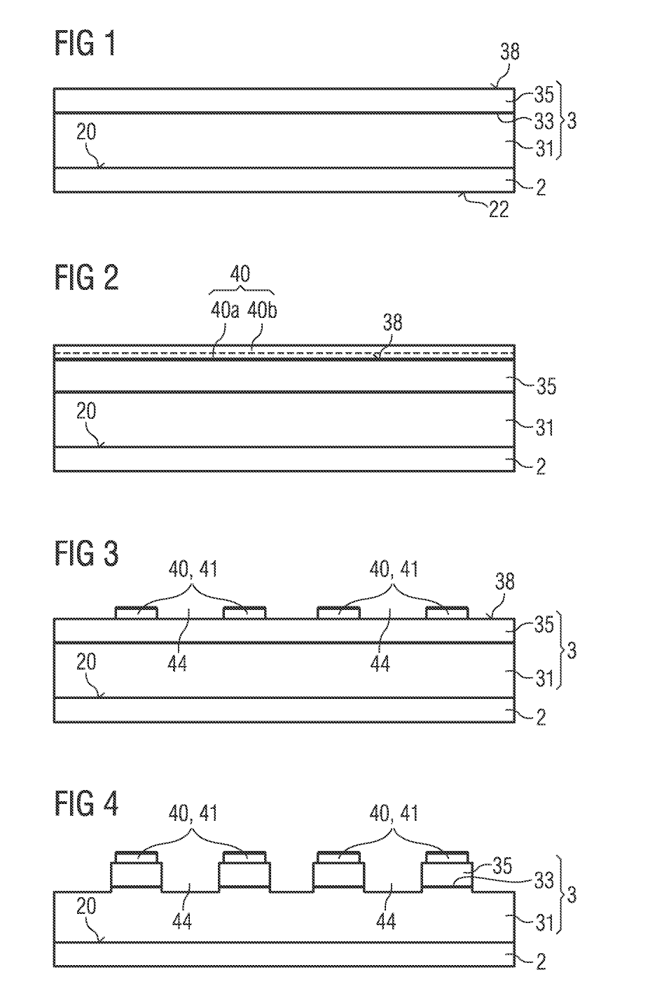

FIGS. 1 to 12 illustrate sectional views of method steps for producing an optoelectronic semiconductor chip 1. Parts located outside the sectional plane, in particular materials located behind the plane of the drawing, are not shown in each case in order to simplify the illustration in FIGS. 1 to 12.

In accordance with FIG. 1, a support 2 is provided. The support 2 is a growth substrate, in particular sapphire. The support 2 comprises a support top side 20 and a front side 22 opposite thereto.

A semiconductor layer sequence 3 is epitaxially deposited onto the support top side 20. The semiconductor layer sequence 3 comprises an n-type n-layer 31 which is located closest to the support 2. Furthermore, the semiconductor layer sequence 3 comprises a p-type p-layer 35. A top side 38 of the semiconductor layer sequence 3 facing away from the support 2 is formed by the p-layer 35.

Located between the n-layer 31 and the p-layer 35 is at least one active layer 33. The active layer 33 can be formed by a pn-transition or by a quantum well structure. Also, for the p-layer 31 and the p-layer 35 it is possible that they are composed of several layers. This is not shown in each case in the simplified illustration in the figures.

The n-layer 31 has, e.g., a thickness of approximately 5 μm and the p-layer 35 has a thickness of approximately 120 nm. The said numerical values, just like all of the numerical values stated hereinafter, also apply in all other exemplified embodiments and, e.g., a tolerance of at the most 50% or a tolerance of at the most 25% is applied thereto.

FIG. 2 illustrates that a contact layer 40 is deposited onto the top side 38. The contact layer 40 comprises a first layer 40a which is formed, e.g., from silver and has a thickness of approximately 600 nm. Alternatively, it can also be a considerably thinner silver layer which is thickened by one or several further metal layers, e.g., copper layers.

Optionally, a second layer 40b of the contact layer 40 is located on the side of the first layer 40a facing away from the support 2. This second layer 40b is formed preferably from a conductive oxide such as ZnO. Adhesion to a subsequently adjoining, dielectric material can be improved by the second layer 40b. The second layer 40b has, e.g., a thickness of approximately 70 nm. The layers 40a, 40b which form the contact layer 40 are deposited preferably onto the entire surface of the top side 38.

FIG. 3 shows that the contact layer 40 is removed partially from the top side 38 in particular by photolithography. As a result, patterning is effected to form contact surfaces 41 for conductor tracks 4 and openings 44 are formed. The contact surfaces 41 surround resulting openings 44 in each case in the manner of a ring or in the shape of a frame. A surface of the openings 44, as seen in plan view, is small in comparison with a remaining surface of the contact surface 41. Contrary to what is suggested by the sectional view in FIG. 3, the contact surfaces 41 cover preferably large parts of the top side 38 of the semiconductor layer sequence 3.

FIG. 4 shows that the p-layer 35 is removed at certain points from the n-layer 31, so that the n-layer 31 is exposed at certain points. The remaining regions of the p-layer 35 can protrude beyond the contact surfaces 41 laterally, in the direction in parallel with the support top side 20. Material of the n-layer 31 is also partially removed, so that the active layer 33 is interrupted.

In accordance with FIG. 5, the semiconductor layer sequence 3 is patterned into individual emitter regions 36. Between adjacent emitter regions 36, a semiconductor material of the semiconductor layer sequence 3 is completely removed. The emitter regions 36 are thus all located on the common support 2. Circumferential bonding onto another substrate does not take place. A mechanical connection of the emitter regions 36 to the support top sides 20 is permanently retained. At this stage of the method, there is no electrical connection between adjacent emitter regions 36.

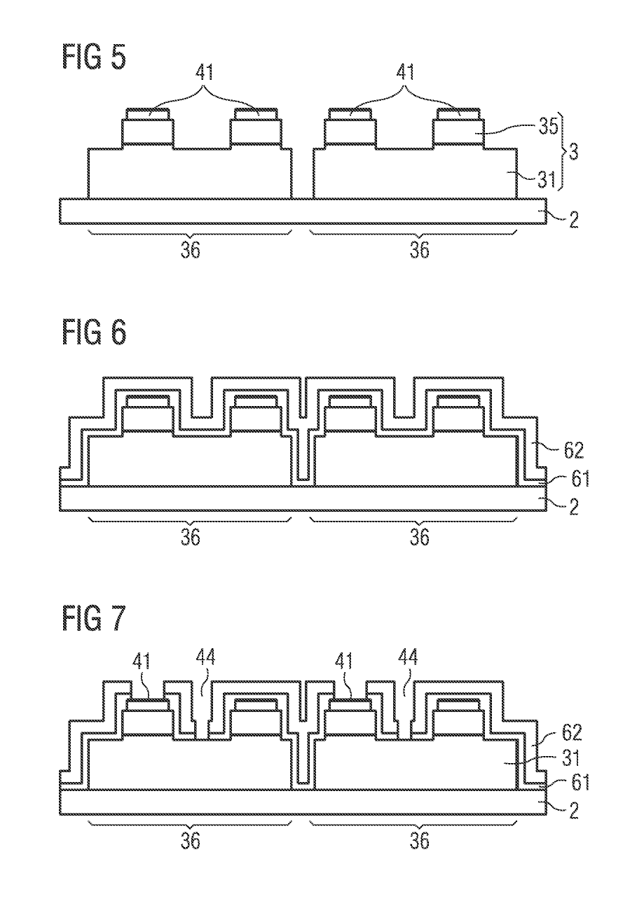

FIG. 6 shows that protective layers 61, 62 are applied all around onto the structures generated in accordance with FIG. 5. The first protective layer 61 which is situated closest to the support 2 is, e.g., an aluminum oxide layer, an aluminum nitride layer, a silicon oxide layer or a silicon nitride layer. An SiO₂:Al layer can also be used.

The second protective layer 62 is deposited onto the first protective layer 61. The second protective layer 62 is, e.g., silicon dioxide/silicon nitride multiple layers. The second protective layer 62 is generated, e.g., by chemical vapor deposition, CVD for short. The second protective layer 62 has a thickness of in particular approximately 400 nm.

In the method step in accordance with FIG. 7, the protective layers 61, 62 are partially removed and the contact surfaces 41 are exposed at certain points Likewise, in the openings 44 the n-layer 31 is partially exposed.

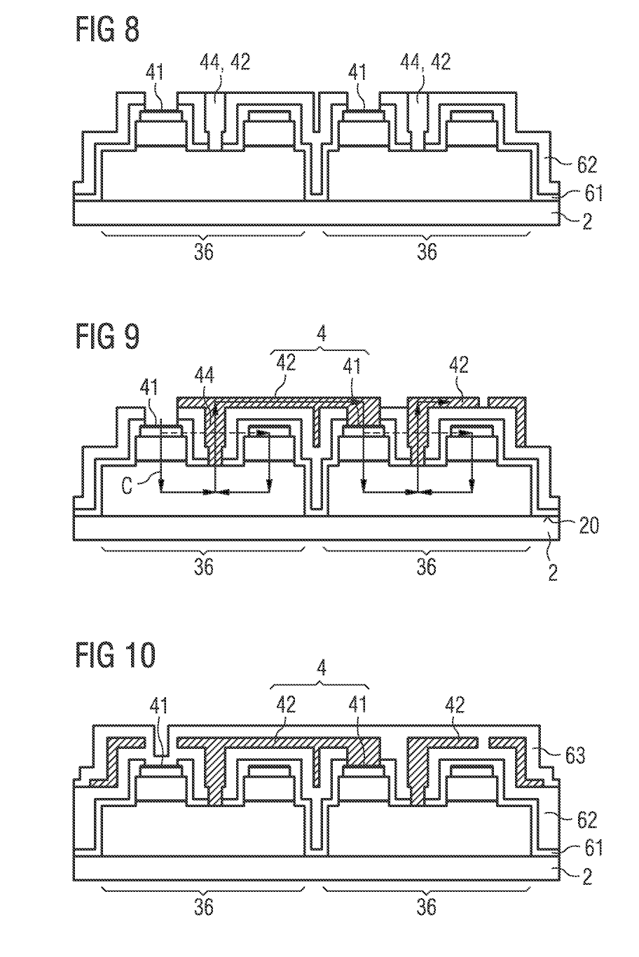

In accordance with FIG. 8, an electrically conductive material for bridges 42 of the conductor tracks 4 is introduced into the openings 44. In order to improve an electrical contact, a contact layer, for instance a ZnO-layer, can optionally be sputtered onto the n-layer 31. Subsequently, the openings 44 are preferably substantially completely filled with a metal, e.g., with silver. After introducing the material of the bridges 42, annealing can be performed.

In the method step in accordance with FIG. 9, the bridges 42 are completed and the conductor tracks 4 are formed. In this method step, in particular the partial regions of the conductor tracks 4 which extend substantially in parallel with the support top side 20 are generated. Each of the conductor tracks 4 comprises in this case one of the contact surfaces 41 and one of the bridges 42. The current paths C resulting therefrom are schematically illustrated in FIG. 9 by arrows. The dashed line arrows between the contact surfaces 41 within one of the emitter regions 36 indicate that the contact surfaces 41 are formed in the manner of a ring around the openings 44.

A material for the bridges 42 is preferably applied substantially over the entire surface. In the layer for the bridges 42 only comparatively small apertures are then present, in order to keep adjacent conductor tracks 4 electrically insulated from one another.

The material for the partial regions of the bridges 42 extending in parallel with the support top side 20 is preferably a reflective material, such as silver. Optionally, in order to promote adhesion, a thin layer of titanium or ZnO can be located towards the contact surfaces 41. In the direction away from the support 2, the bridges 42 can be covered by a thin platinum layer and/or by a thin titanium layer, likewise to improve adhesion to subsequent layers. Therefore, an adhesion-promoting layer can be located on one or on both sides of the bridges 42, in a direction perpendicular to the support top side 20. The partial regions of the bridges 42 extending in parallel with the support top side 20 have, e.g., a thickness of approximately 150 nm or of approximately 350 nm.

In accordance with FIG. 10, a third protective layer 63 is deposited onto the entire surface, e.g., by CVD. A material of the third protective layer 63 is, e.g., silicon nitride. A thickness of the third protective layer 63 can be in the region of approximately 500 nm.

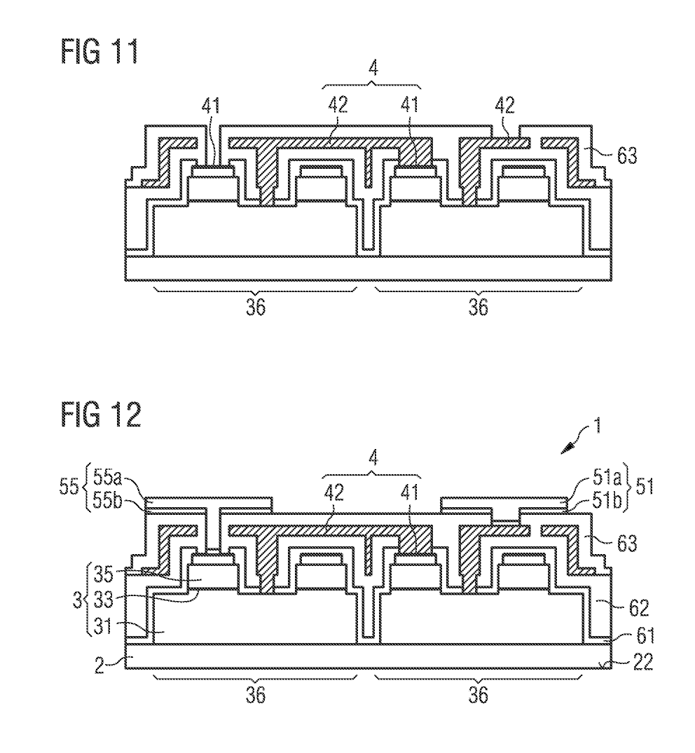

FIG. 11 shows that two recesses are formed in the third protective layer 63, which means that one of the contact surfaces 41 and one of the bridges 42 is exposed.

In accordance with FIG. 12, the semiconductor chip 1 is completed in that an n-contact point 51 and a p-contact point 55 are formed. Optionally, the contact points 51, 55 are constructed in multiple layers. An optional first layer 51b is formed, e.g., from titanium and/or titanium-tungsten-nitride and can function as a barrier layer, diffusion stopping layer and/or adhesion promoting layer. A second layer 51a, 55a is formed onto the first layer 51b, 55b. The second layer 51a, 55a is preferably solderable and can be formed from AuSn. A thickness of the contact points 51, 55 is, e.g., between 200 nm and 3 μm inclusive.

The semiconductor chip 1 in accordance with FIG. 12 comprises only two emitter regions 36. In contrast to the illustration, a larger number of emitter regions 36 can be present. At each of the emitter regions 36, a voltage drop of approximately 3 V occurs. In the case of, e.g., four emitter regions 36, the semiconductor chip 1 is then operated with a voltage of approximately 12 V. In the case of correspondingly more emitter regions 36, a correspondingly higher operating voltage can be achieved.

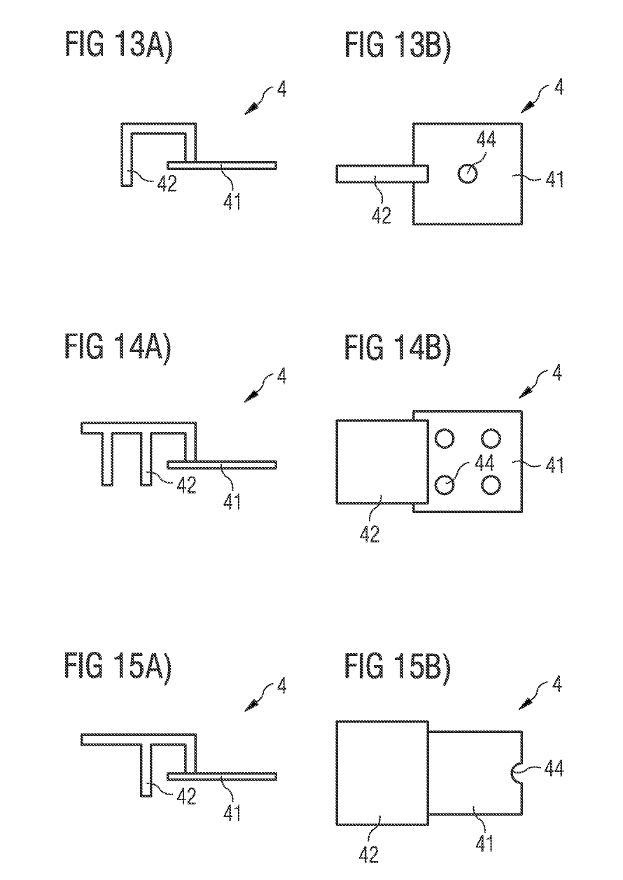

FIGS. 13 to 15 schematically illustrate possible embodiments of the conductor tracks 4, parts A of the figures relate in each case to a schematic lateral view and parts B of the figures relate in each case to a schematic plan view. FIGS. 13 to 15 illustrate various aspects of the conductor tracks 4. In this case, mixed forms can also occur between the conductor tracks, illustrated in FIGS. 13 to 15, in a semiconductor chip, for instance in accordance with FIG. 12.

In accordance with FIG. 13, the contact surface 41 of the conductor tracks 4 comprises precisely one opening 44 and the bridge 42 is, as seen in plan view, formed in the manner of track and is U-shaped as seen in a lateral view. A region of the bridge 42 extending perpendicularly to the contact surface 41 intersects a plane defined by the contact surface 41.

In accordance with FIG. 14, the contact surface 41 comprises a plurality of openings 44. The openings 44 are preferably regularly arranged in a grid. The bridge 42 is formed in a planar manner, so that together with the contact surface 41 a minor covering substantially the entire surface is formed for the emitter regions 36. As seen in the lateral view, the bridge 42 can be F-shaped or πr-shaped.

As also in the case of all of the other exemplified embodiments, a diameter of the openings 44 is, e.g., at least 5 μm and/or at the most 25 μm. The size of the openings 44 is preferably as small as possible.

In the case of the conductor track 4, as shown in FIG. 15, the opening 44 is located on an edge of the contact surface 41. The opening 44 is formed as a lug. The bridge 42 is formed in a planar manner and preferably almost completely spans the contact surface 41 of an adjacent conductor track, not shown.

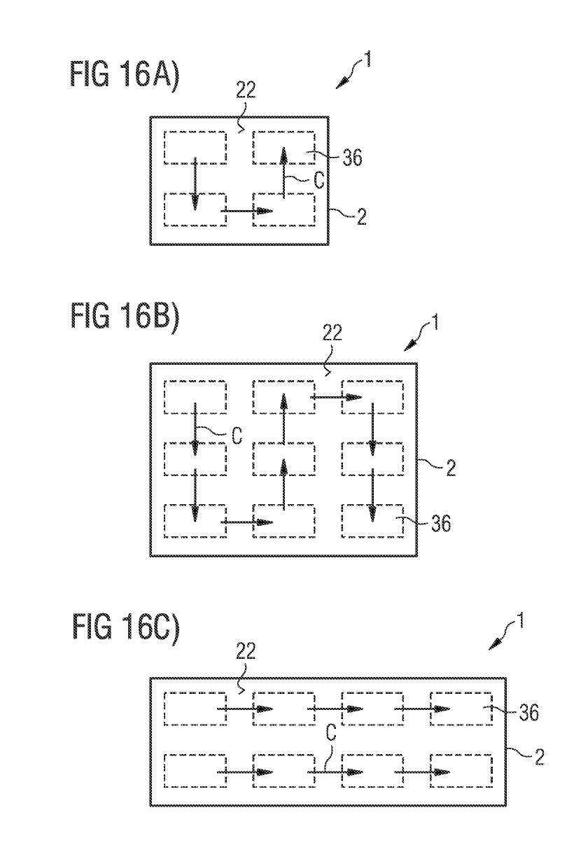

FIG. 16 shows further exemplified embodiments of the semiconductor chips 1, in plan views of the front side 22. The front side 22 is configured as a radiation main side. The semiconductor chips 1 comprise, e.g., an edge length of at least 0.25 mm or at least 0.5 mm or at least 0.75 mm. Alternatively or in addition, the edge length is at the most 3 mm or at the most 2 mm.

None of the front sides 22 are interrupted by conductor tracks or through vias. That is to say that the support 2 preferably does not comprise any holes, gaps or recesses to effect electrical and/or mechanical contacting. The support 2 extends in a contiguous and uninterrupted manner over all of the emitter regions 36.

In accordance with FIG. 16A, the semiconductor chip 1 comprises four emitter regions 36 which are arranged in a square pattern and all are electrically connected in series, see, e.g., the current direction C denoted by arrows.

In FIG. 16B, the semiconductor chip 1 comprises nine emitter regions 36 which are arranged in a uniform grid and which are likewise combined in a single electrical series connection.

In contrast thereto, the semiconductor chip 1 in accordance with FIG. 16C comprises two separate series connections which each comprise, e.g., four emitter regions 36. Accordingly, the semiconductor chip 1 in accordance with FIG. 16 comprises a number of n-contact points and p-contact points, not shown, corresponding to the number of series connections.

1-15. (canceled)

16. An optoelectronic semiconductor chip comprising:
a support having a support top side;
a semiconductor layer sequence having at least one active layer for generating electromagnetic radiation, wherein the active layer is located between an n-type n-layer and a p-type p-layer of the semiconductor layer sequence, wherein the semiconductor layer sequence, as seen in a plan view of the support top side, is patterned into at least two emitter regions arranged next to one another;
at least two electrical conductor tracks located on a side of the semiconductor layer sequence facing away from the support, where each of the at least two electrical conductor tracks comprises a contact surface; and
an n-contact point and a p-contact point for electrically contacting the semiconductor chip,
wherein the emitter regions are electrically connected in series via the at least two conductor tracks.

17. The optoelectronic semiconductor chip according to claim 16,
wherein the contact surface comprises at least one opening through which a further conductor track extends as far as into the n-layer,
wherein conductor tracks of the at least two electrical conductor tracks that are not electrically directly connected to the n-contact point or the p-contact point comprise an electrically conductive bridge,
wherein the conductive bridge electrically connects two adjacent emitter regions to one another and in each case partially covers these emitter regions, as seen in a plan view of the support top side,
wherein all of the contact surfaces lie in a common plane in parallel with the support top side,
wherein partial regions of the conductive bridges extending in parallel with this plane are located further away from the support top side than the contact surfaces,
wherein partial regions of the n-contact point and the p-contact point extending in parallel with this plane are further away from the support top side than the contact surfaces and the conductive bridges, and
wherein the conductive bridges are configured in a planar manner, so that together with the contact surfaces a mirror which covers an entire emitter regions is formed.

18. The optoelectronic semiconductor chip according to claim 16, wherein the at least two conductor tracks follow one another along a current direction of a series connection and penetrate one another.

19. The optoelectronic semiconductor chip according to claim 18,
wherein conductor tracks of the at least two electrical conductor tracks that are not electrically directly connected to the n-contact point or the p-contact point comprise a contact surface which is located on the p-layer,
wherein the contact surface comprises at least one opening, through which a further conductor track extends as far as into the n-layer.

20. The optoelectronic semiconductor chip according to claim 19,
wherein the conductor tracks that are not electrically directly connected to the n-contact point or the p-contact point comprise an electrically conductive bridge,
wherein the conductive bridge electrically connects two adjacent emitter regions to one another and in each case partially covers these emitter regions, as seen in a plan view of the support top side.

21. The optoelectronic semiconductor chip according to claim 20,
wherein in each case precisely one of the contact surfaces of the conductor tracks is mounted on precisely one of the emitter regions, and
wherein each of the contact surfaces is penetrated by the conductive bridge of a conductor track adjacent to in the current direction.

22. The optoelectronic semiconductor chip according to claim 20,
wherein all of the contact surfaces lie in a common plane in parallel with the support top side,
wherein partial regions of the conductive bridges extending in parallel with this plane are located further away from the support top side than the contact surfaces, and
wherein partial regions of the n-contact point and the p-contact point extending in parallel with this plane are further away from the support top side than the contact surfaces and the conductive bridges.

23. The optoelectronic semiconductor chip according to claim 16, wherein at least one partial region of the conductor tracks is configured as a reflector for radiation generated in the active layer.

24. The optoelectronic semiconductor chip according to claim 16, wherein the support is a growth substrate for the semiconductor layer sequence.

25. The optoelectronic semiconductor chip according to claim 16, which is a flip-chip and wherein a radiation main side is formed by a front side of the support opposite to the support top side.

26. The optoelectronic semiconductor chip according to claim 16,
wherein, as seen in a plan view of the support top side, conductor tracks which are adjacent in a current direction overlap, and
wherein the conductor tracks are electrically connected to one another only via the semiconductor layer sequence.

27. The optoelectronic semiconductor chip according to claim 16, wherein the semiconductor layer sequence is completely removed between adjacent emitter regions so that there is no continuous connection between adjacent emitter regions, and wherein the semiconductor layer sequence comprises a semiconductor material.

28. The optoelectronic semiconductor chip according to claim 16, wherein a trench between adjacent emitter regions is completely filled with at least one electrically insulating material.

29. The optoelectronic semiconductor chip according to claim 16, wherein the semiconductor chip comprises between 4 and 24 emitter regions inclusive.

30. A method for producing an optoelectronic semiconductor chip according to claim 16, the method comprising:
providing the support;
epitaxially growing the semiconductor layer sequence onto the support top side;
applying a contact layer for the conductor tracks onto a top side of the semiconductor layer sequence facing away from the support;
patterning the contact layer to form contact surfaces of the conductor tracks;
patterning the semiconductor layer sequence to form the emitter regions;
applying at least one electrically insulating protective layer onto the top side;
applying electrically conductive bridges of the conductor tracks, wherein the conductive bridges electrically connect adjacent emitter regions to one another; and
applying the n-contact point and the p-contact point.

31. An optoelectronic semiconductor chip comprising:
a support having a support top side;
a semiconductor layer sequence having at least one active layer for generating electromagnetic radiation, wherein the active layer is located between an n-type n-layer and a p-type p-layer of the semiconductor layer sequence, and wherein the semiconductor layer sequence, as seen in a plan view of the support top side, is patterned into at least two emitter regions arranged next to one another;
at least two electrical conductor tracks located on a side of the semiconductor layer sequence facing away from the support, wherein the at least two electrical conductor tracks comprise contact surfaces, wherein a contact surface comprise at least one opening, through which a further conductor track extends as far as into the n-layer, and wherein the emitter regions are electrically connected in series via the at least two conductor tracks; and
an n-contact point and a p-contact point for electrically contacting the semiconductor chip,
wherein the conductive bridge electrically connects two adjacent emitter regions to one another and in each case partially covers these emitter regions, as seen in a plan view of the support top side,
wherein the conductive bridges are configured in a planar manner so that the conductive bridges together with the contact surfaces form a mirror covering an entire emitter regions;
wherein all of the contact surfaces lie in a common plane in parallel with the support top side,
wherein partial regions of the conductive bridges extending in parallel with this plane are located further away from the support top side than the contact surfaces, and
wherein partial regions of the n-contact point and the p-contact point extending in parallel with this plane are further away from the support top side than the contact surfaces and the conductive bridges.
